(19) United States
(12) Patent Application Publication
(10) Pub. No.: US 2008/0084244 A1
(43) Pub. Date: Apr. 10, 2008

(54) Method And System For Linearizing The Characteristic Curve Of A Power Amplifier

(76) Inventor: Bjorn Jelonnek, Ulm (DE)

Correspondence Address: STAAS & HALSEY LLP, SUITE 700, 1201 NEW YORK AVENUE, N.W., WASHINGTON, DC, 20005, US

(21) Appl. No.: 11/631,697

(22) PCT Filed: Apr. 8, 2005
(86) PCT No.: PCT/EP05/51564

§ 371 Date: Jan. 5, 2007

(30) Foreign Application Priority Data
Jul. 6, 2004 (EP) 04015907.1

(51) Int. Cl. H03F 1/32

(52) U.S. Cl. 330/149

(57) ABSTRACT

According to a method, a first signal is produced from a digital input signal by pre-emphasis and said signal is supplied, after carrier frequency translation, D/A conversion and modulation, to a power amplifier for producing a carrier-frequency output signal. IN order to linearize the characteristic curve of the power amplifier, pre-emphasis is carried out in a manner controlled by parameters. A test signal is superposed to the first signal, thereby producing an output signal having a carrier-frequency test signal portion in addition to a carrier-frequency input signal portion. A comparison of the carrier-frequency test signal portion of the output signal with the test signal yields the parameter for controlling pre-emphasis. Alternatively, the test signal can be superposed before the pre-emphasis to be carried out.

### CROSS REFERENCE TO RELATED APPLICATIONS

This application is based on and hereby claims priority to Application No. PCT/EP/2005/051564 filed on Apr. 8, 2005 and European Application No. 04015907 filed Jul. 6, 2004, the contents of which are hereby incorporated by reference.

### BACKGROUND

The invention relates to a method for linearizing the characteristic curve of a power amplifier and also to a system for linearizing the characteristic curve of a power amplifier.

Power amplifiers, which ideally are designed for highly-linear amplification of broadband carrier-frequency signals, are used for the transmission of telecommunications signals. Pre-emphasis methods are known for optimizing the characteristic curve of a power amplifier in respect of its linearity. In such cases, for forming a linearly-amplified output signal, the signal to be transmitted is pre-emphasized before amplification so as to compensate for non-linearities of the characteristic amplifier curve.

The pre-emphasis is normally undertaken in what is known as the intermediate frequency range or in the complex baseband of the signal, i.e. before the conversion into the carrier frequency range, with the pre-emphasis being adjusted with the aid of parameters. The parameters in their turn are obtained from a comparison of the power amplifier output signal with the signal before the pre-emphasis and/or after the completed pre-emphasis. This means that the parameters determined depend both on the properties of the signal to be transmitted and on the operating parameters of the power amplifier and are thus influenced both by the electrical characteristic data of the amplifier and by its ambient temperature.

The parameters for control of the pre-emphasis are usually stored in a multi-dimensional table and can be re-used when appropriate circumstances occur, which also allows account to be taken of changing ambient temperatures.

Because of the above-mentioned dependencies of the parameters, these types of table are very extensive and the parameters are only able to be adapted using very time-consuming procedures.

A method for pre-emphasis is known from US 2002/68023 A1, in which a coupled-in test signal is amplified and subsequently analyzed after the pre-emphasis.

A method for pre-emphasis is known from WO 00/02324 A1, in which a pilot signal is coupled in before the pre-emphasis is executed and analyzed after completed amplification.

### SUMMARY

One possible object of the present invention is thus to specify a method and a system for a fast and precise linearization of a power amplifier characteristic curve to be executed in which the linearization is to be performed by a signal pre-emphasis.

The inventor suggests that a first signal, which is present for example as a multi-carrier signal is superposed by a test signal and thereby a second signal is formed. The second signal is converted into a carrier frequency slot and fed to a power amplifier to form an output signal. Especially by comparing a test signal component contained in the output signal with the test signal, parameters to control a pre-emphasis are formed.

In a first embodiment an input signal is pre-emphasized in order to form the first signal, with the input signal being present as a multi-carrier signal in the complex digital baseband or translated in an intermediate frequency slot.

In a second embodiment the first signal is present as a multi-carrier signal in the complex digital baseband or translated in an intermediate frequency slot and is not pre-emphasized until after completed test signal superposition.

The test signal exhibits particular spectral characteristics. Preferably a pulse signal is used which has a time-variant amplitude value distribution known in advance. The individual amplitudes are selected so that only negligible disturbance components dependent on the test signal are formed in those frequency ranges which are adjacent to a carrier frequency range to be used.

Advantageously further parameters are obtained especially from the test signal component contained in the output signal by comparison with the test signal, with which the formation of the test signal is controlled. This makes possible the suppression of the above-mentioned disturbance components in the adjacent frequency ranges.

In an advantageous development of the invention a baseband clipping method is executed in the baseband on the signal which is to be used in subsequent execution for superposition with the test signal. By analyzing the output signal it is possible to form parameters for controlling the baseband clipping method.

The baseband clipping method is thus applied to the complex baseband signal from which, after the baseband clipping method has been executed, after interpolation and modulation and if necessary after pre-emphasis has been performed, the first signal is produced in the first embodiment.

The baseband clipping method is used to reduce possible maximum transmit power values of the output signal to a fixed predetermined value. The baseband clipping method is not used for smaller amplitudes of the baseband signal.

Advantageously in this case a flexibly adjustable clipping threshold is used which can be changed in accordance with the instantaneously available maximum power of the power amplifier. This instantaneously available maximum power is especially dependent on the ambient temperature of the power amplifier. The parameters for controlling the clipping method are determined as a function of the ambient temperature and stored in the table for subsequent variation of the clipping threshold.

The design of the test signal and the use of the test signal in the assessment of the behavior of the power amplifier make it possible to reduce the number of entries contained in the table. Characteristics or operating states of the amplifier are detected and compensated for more quickly. This reduced-sized table is especially advantageous for rapid changes in the complex baseband input signal.

It is possible to consider the baseband clipping method and the pre-emphasis method as uniform for the respective overall embodiment, in which case corresponding settings make it possible for them to complement each other.

With the above, it is easy to perform an adaptive adjustment of the clipping threshold of the baseband clipping method.

### BRIEF DESCRIPTION OF THE DRAWINGS

These and other objects and advantages will become more apparent and more readily appreciated from the following description of the preferred embodiments, taken in conjunction with the accompanying drawings of which:

FIG. 1 a block diagram of a system for linearization of a power amplifier characteristic curve according to a first embodiment,

FIG. 2 a block diagram of a system for linearization of a power amplifier characteristic curve according to a second embodiment,

FIG. 3 a typical test signal with reference to FIG. 1 and FIG. 2,

FIG. 4 a test signal frequency response with reference to FIG. 3,

FIG. 5 the signal timing waveform of the output signal with reference to FIG. 1 and FIG. 2,

FIG. 6 a complex diagram of the output signal with reference to FIG. 1 and FIG. 2,

FIG. 7 the output signal frequency response with reference to FIG. 1 and FIG. 2,

FIG. 8 an output signal frequency response measured on a receiver side, and

FIG. 9 a comparison of an adaptation result obtained with a non-linear amplifier characteristic curve.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

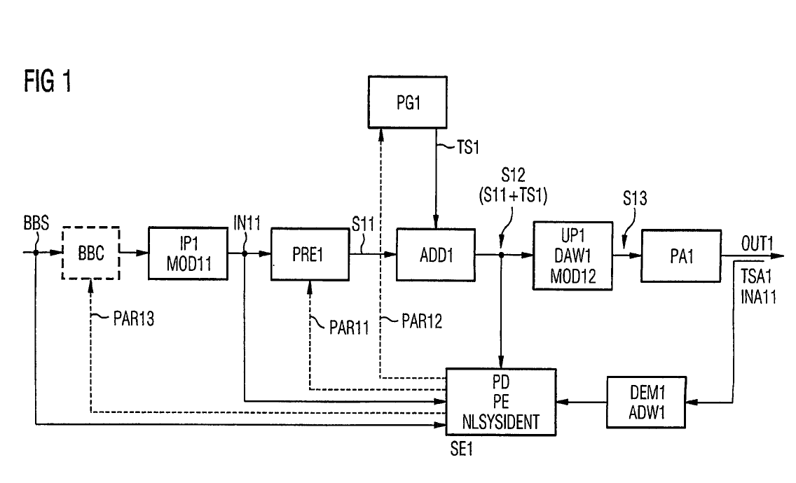

FIG. 1 shows a block diagram of a first arrangement for linearization of a power amplifier characteristic curve of a power amplifier PA1.

One or more complex baseband signals BBS reach an interpolation device IP1 and are translated using a first modulator MOD11 into a (multicarrier) input signal IN11, with the input signal IN11 for example being present as an oversample in an intermediate frequency slot. The input signal IN11 formed reaches a pre-emphasis unit PRE1 and is pre-emphasized by this unit, producing a pre-emphasized first signal S11. The pre-emphasis unit PRE1 is controlled by a first parameter set PAR11.

The first signal S11 reaches an additive superposition unit ADD1, to which a test signal TS1 formed by a pulse generator PG1 is also fed.

A second signal S12 is formed for example with the aid of the additive superposition unit ADD1 by additive superposition to the first signal S11 of the test signal TS1.

The second signal S12 arrives via a device for carrier frequency translation UP1, via a D/A converter DAW1 and via a second modulator MOD12 as a third carrier-frequency signal S13 at the power amplifier PA1, which exhibits a non-linear characteristic amplifier curve. The power amplifier PA1 forms from the third signal S13 a power-amplified, carrier-frequency output signal OUT1.

The carrier-frequency output signal OUT1 thus has both components of the input signal IN11 and also components of the test signal TS1. These are referred to below as test signal component TSA1 and as input signal component INA11.

Proportions of the output signal OUT1 arrive for example by uncoupling via a demodulator DEM1 and via an A/D converter ADW1 at a control device SE1, to which the second signal S12 is also fed. As described above, the second signal S12, because of the superposition, also contains the test signal TS1 as well as the first signal S11.

The control device SE1 analyzes the transmission of the test signal TS1 by comparing a time segment with the test signal component TSA1 of the output signal OUT1 with the corresponding time segment of the test signal TS1. Based on this comparison, the first parameter set PAR11, with which the pre-emphasis unit PRE1 is controlled, is formed by the control device SE1. The linearization of the characteristic curve of the power amplifier PA1 is achieved by this control.

For more precise determination of the parameter set PAR11, an additional comparison of the input signal component INA11 contained in the output signal OUT1 with the input signal IN11 is possible in an advantageous further development.

In a further advantageous development a further parameter set PAR12 with which the pulse generator PG1 will be controlled is formed by the control device SE1. This parameter set PAR12 is also formed by comparison of the test signal component TSA1 of the output signal OUT1 with the test signal TS1.

The control of the formation of the test signal TS1 makes it possible to minimize disruptive carrier-frequency components of the test signal TSA1 in those frequency ranges which are adjacent to a carrier frequency range of the output signal OUT1 to be used. Overloading of the power amplifier is avoided.

The parameter sets PAR11 and PAR12 are determined with the aid of a peak detection method PD, of a power estimation method PE and/or of a so-called “NL system identification” method NLSYSIDENT with target functions. These methods are known for example from the book entitled “Digital Communications”, John G. Proakis, pages 601-635. The associated algorithms of the target functions can be found in this book on pages 636 to 679.

Methods for pre-emphasis are known for example from the German patent application with the file reference DE 103 20 420 A1, which was submitted to the German patent and trademark office on 07.05 2003. In this application a projection of an undersampled output signal of an AD converter is computed on different basic vectors which are obtained from a pre-emphasized signal. The projection can for example be undertaken in the form of a power series development.

In an advantageous development, the complex baseband signal BBS is additionally fed to the control device SE1 and additionally compared with the input signal component INA11 contained in the output signal OUT and/or with the first signal S11 contained in the second signal S12. This makes a more precise determination of the parameter set PAR11 possible.

In addition a baseband clipping method BBC can be applied to the complex baseband signal BBS. In this case a further parameter set PAR13 which is used for control of the baseband clipping method is formed by the control device SE1. When the parameter set PAR13 is formed the second signal S12 and/or the input signal IN11 are taken into account, in addition to the output signal OUT1.

An adaptive setting of a clipping threshold of the baseband clipping process BBC is implemented, with this threshold being adapted to the overall system or to its transmission characteristics. This adaptation can for example be undertaken as described below. A maximum amplitude of the power amplifier PA1, which lies far above a maximum value of the third signal S13, is known from the computed parameters of the parameter set PAR11 or from the use of the peak detection method PD. This means that the clipping threshold value can be adapted to characteristics of the power amplifier PA1, especially to its ambient temperature, ageing, dispersion, . . . , or to peak values of the output power of the output signal OUT1 which depend on these characteristics.

Furthermore, for an impending overload of the power amplifier PA1, higher signal levels of the baseband signal BBS are more greatly reduced by the baseband clipping method BBS than would be the case in a normal application. In addition the test signal TS1 is then superposed to the first signal S11, with the correct phase, but with a negative amplitude, in order to reduce the maximum amplitude of the output signal OUT1.

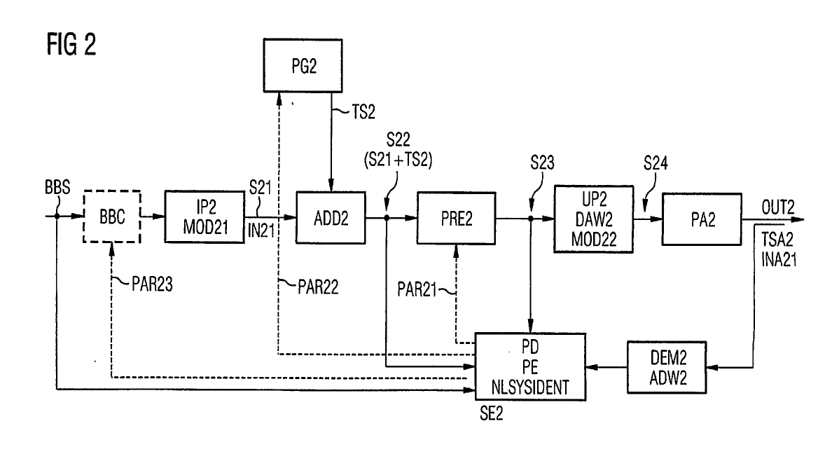

FIG. 2 shows as a block diagram a second arrangement for linearization of the characteristic curve of a power amplifier PA2.

The complex baseband signals BBS reach an interpolation device IP2 either via a device for executing a baseband clipping method BBC or directly, and are translated using a first modulator MOD21 into a (multicarrier) input signal IN21, with the input signal IN21 being present oversampled in an intermediate frequency slot.

The input signal IN21 reaches an additive superposition device ADD2 as first signal S21, with a test signal formed by a pulse generator PG2 also being fed to said device.

A second signal S22 is formed for example with the aid of the additive superposition device ADD2 by additive superposition to the first signal S21 of the test signal TS2.

The second signal S22 reaches a pre-emphasis unit PRE2 and is pre-emphasized by this unit, with a pre-emphasized third signal S23 being formed. The pre-emphasis unit PRE2 is controlled by a first parameter set PAR21.

The third signal S23 arrives via a device for carrier frequency translation UP2, via a D/A converter DAW2 and via a second modulator MOD22 as a fourth carrier-frequency signal S24 at the power amplifier PA2 which has a non-linear characteristic amplifier curve. The power amplifier PA2 forms a power amplifier carrier-frequency output signal OUT2 from the fourth signal S24.

Thus the carrier-frequency output signal OUT2 has both components of the first signal S21 or of the input signal IN21 and also components of the test signal TS2. These will be referred to below as input signal component INA21 and as test signal component TSA2.

The output signal OUT2, for example by uncoupling via a demodulator DEM2 and via an A/D converter ADW2, proportionally reaches a control device SE2, to which the second signal S22 and/or the third signal S23 are also fed.

As described above, the second signal S22, because of the superposition, also contains the test signal TS2 in addition to the first signal S21.

The control device SE2 analyzes the transmission of the test signal TS2 by comparing the test signal component TSA2 of the output signal OUT2 with the test signal TS2 contained in the second signal S22. Based on this comparison, the first parameter set PAR21 with which the pre-emphasis unit PRE2 is controlled is formed by the control device SE2. A linearization of the characteristic curve of the power amplifier PA2 is achieved by this control.

For more precise determination of the parameter set PAR21 an additional comparison of the input signal component INA21 contained in the output signal OUT2 with the first signal S21 contained in the second signal S22 and/or with the third signal S23 is possible in an advantageous further development.

In an advantageous development a further parameter set PAR22, with which the pulse generator PG2 is controlled, is formed by the control device SE2. To form the parameter set PAR22 the test signal component TSA2 contained in the output signal OUT2 is again compared to the test signal TS2 contained in the second signal S22 in assigned time segments.

In an advantageous development signal components of the output signal OUT2 or of the second signal S22 which can additionally be assigned to one another are evaluated.

By controlling the formation of the test signal TS2 it is possible to minimize disruptive components of the test signal TSA2 in those frequency ranges which are adjacent to a carrier frequency range of output signal OUT2 to be used.

The parameter sets PAR21 and PAR22 are determined using the method already described in FIG. 1.

In an advantageous development the control device SE2 is additionally supplied with the complex baseband signal BBS. It is also possible to determine the parameter set PAR21 more precisely by an additional comparison of the baseband signal BBS with the input signal component INA21 contained in the output signal OUT2 and/or with the input signal IN21 contained in the second signal S22 which corresponds to the first signal S21, and/or with the corresponding input signal component of the third signal S23.

When the device BBC for executing the baseband clipping method is used, a further parameter set PAR23 is formed by the control device SE2 which controls the baseband clipping method. The complex baseband signal BBS and/or the second signal S22 and/or the third signal S23 are taken into account in addition to the output signal OUT2 in the formation of the parameter set PAR23.

This implements an adaptive adjustment of a clipping threshold value which is used for the baseband clipping method BBC. This clipping threshold is adaptively matched to the overall system or to its transmission characteristics.

This adaptation can for example be undertaken as described below. A maximum amplitude of the power amplifier PA2 which lies far above a maximum value of the fourth signal S24 is known from the calculated parameters of the parameter set PAR21 or from the use of the peak detection method PD. Thus the clipping threshold can be adapted to characteristics of the power amplifier PA2, especially to its ambient temperature, ageing, dispersion, etc., or to the peak values of the output power of the output signal OUT2 which depend on such characteristics.

In a further application, if there is the threat of overloading of the power amplifier PA2, higher signal levels of the baseband signal BBS are further reduced. In addition a test signal TS2 is additively superimposed with the correct phase but with a negative amplitude onto the input signal IN21. A maximum amplitude of the output signal OUT2 is reduced in this way.

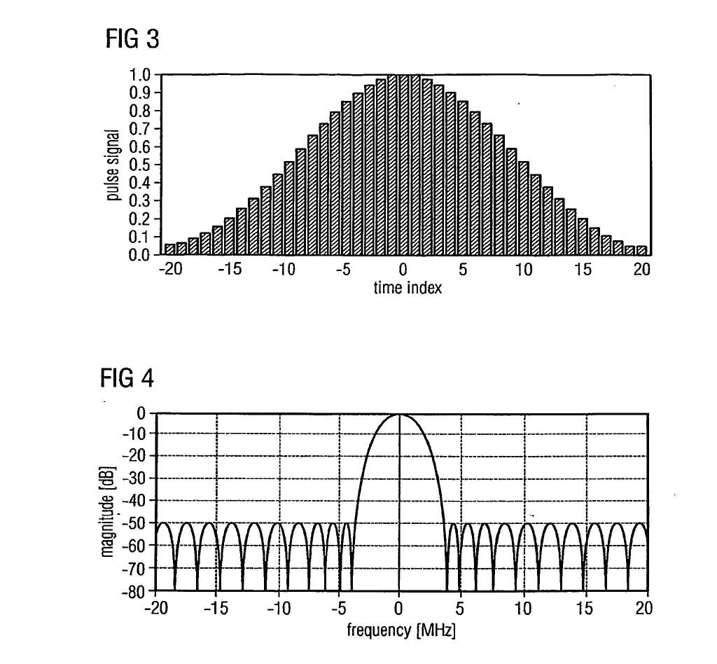

FIG. 3 shows, with reference to FIG. 1 and FIG. 2, a typical test signal TS1 or TS2 which exhibits time-variant amplitude statistics.

The time is plotted on the horizontal axis and corresponding pulse signals are plotted on the vertical axis. Test signal TS1 or TS2 has been selected here as a Chebyshev design with 41 coefficients and a blocking attenuation of 50 dB. In this case the objective of the test signal was to define a signal limited to 31 time values, of which the essential spectral components lie in the carrier frequency band to be used.

FIG. 4 shows, with reference to FIG. 3, the frequency response of the test signal TS1 or TS2, with the frequency plotted on the horizontal axis and associated amplitude values plotted on the vertical axis.

In this case the test signal has an identical complex phase to the maximum useful signal S11 or S21 in the complex baseband.

FIG. 5 shows, in relation to FIG. 1 and FIG. 2, the timing of output signals OUT1 or OUT2, with the time plotted on the horizontal axis and the amplitudes plotted on the vertical axis. The superposed test signal can be seen clearly in this diagram at t=2*10⁵.

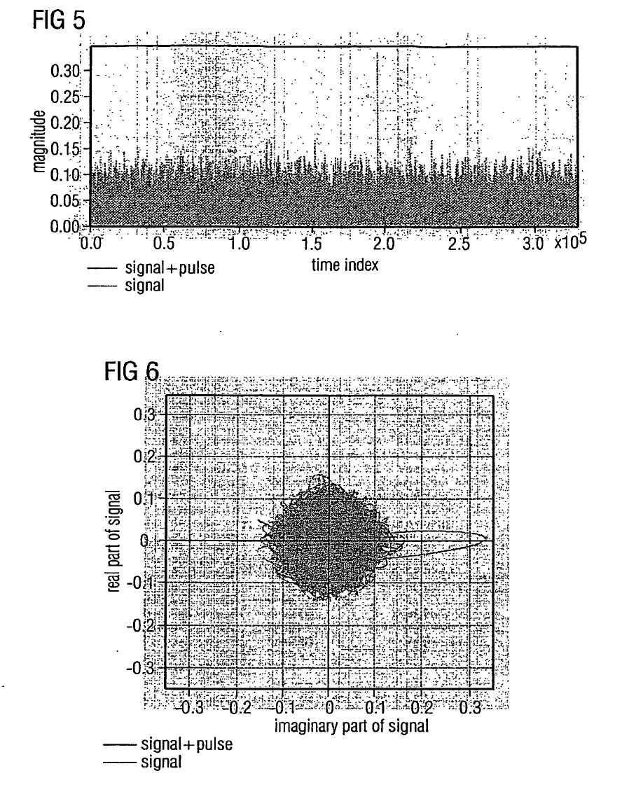

FIG. 6 shows a more complex diagram of the output signal OUT1 or OUT2 in relation to FIG. 1 and FIG. 2. In this case the superposed test signal can clearly be seen in a club-shaped waveform.

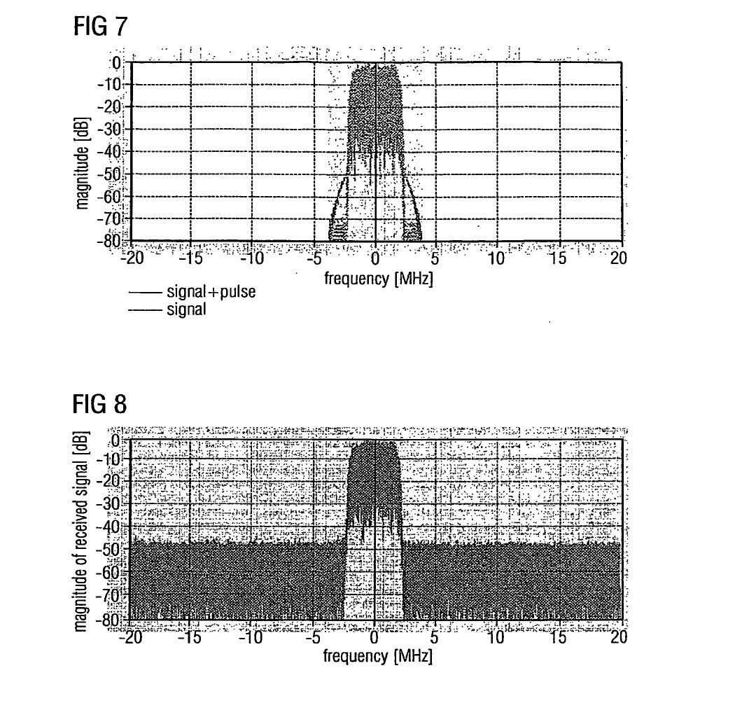

FIG. 7 shows, in relation to FIG. 6, the frequency response of the output signal OUT1 or OUT2, with the frequency being plotted on the horizontal axis and amplitudes being plotted on the vertical axis.

FIG. 8 shows, in relation to FIG. 7, an output signal frequency response measured by a receiver, with the frequency being plotted on the horizontal axis and receive amplitudes being plotted on the vertical axis. This assumes the measured signal will be disturbed by additively superposed, white, Gaussian distributed noise.

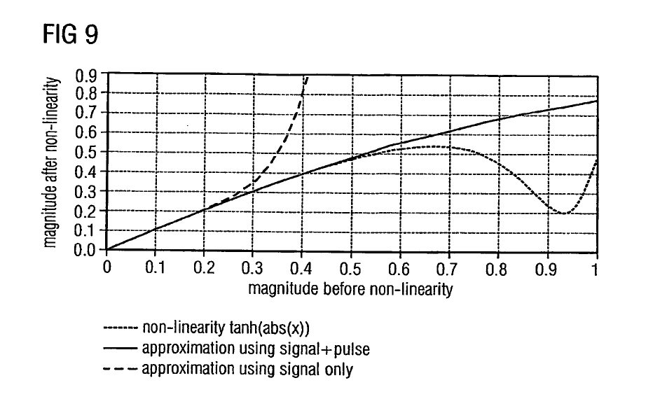

FIG. 9 shows a comparison of an adaptation result obtained on a non-linear characteristic amplifier curve, labeled “non-linearity tanh(abs(x))”. This is the middle characteristic curve shown in FIG. 9.

A magnitude of the amplitude of the third signal S13 or of the fourth signal S24 is shown on the horizontal axis. A magnitude of the amplitude of the output signal OUT1 or OUT2 is shown on the vertical axis—after a demodulation and analog/digital conversion to be performed.

A variation of a conventional estimate of non-linearity of the characteristic amplifier curve with increasing amplitude curve can be seen with the curve labeled “approximation using signal only”. This is the left-hand characteristic curve shown in FIG. 9.

By contrast, the estimated non-linearity for the application of the test signal labeled as “pulse” is significantly longer in compliance with the non-linear characteristic amplifier curve—curve labeled with “approximation using signal+pulse”. This is the right-hand characteristic curve shown in FIG. 9.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-18. (canceled)

19. A method for linearizing a characteristic curve of a power amplifier, comprising:
forming a first signal from a digital input signal by pre-emphasis, the pre-emphasis being controlled using parameters to thereby linearize the characteristic curve of the power amplifier;
feeding a second signal, after carrier frequency conversion, a D/A-conversion and a modulation to a power amplifier to form a carrier-frequency output signal, which has a carrier-frequency input component;
superposing a test signal to the first signal to form the second signal, whereby the output signal has the carrier-frequency input component and additionally has a carrier-frequency test signal component; and
forming the parameters for control of the pre-emphasis by performing a comparison of the carrier-frequency test signal component of the output signal with the test signal wherein
the test signal is formed in a controlled manner by parameters which are formed from the comparison of the carrier-frequency test signal component of the output signal with the test signal.

20. The method as claimed in claim 19, wherein for forming the parameters for control of the pre-emphasis, an additional comparison of the carrier frequency input component with the first signal and/or with the digital input signal is executed.

21. The method as claimed in claim 19, wherein
the power amplifier has a carrier frequency range,
a pulse signal with a time-variant amplitude statistic is used as the test signal, and
the test signal has individual amplitudes which are negligibly disruptive components in carrier frequency ranges adjacent to the carrier frequency range of the power amplifier.

22. The method as claimed in claim 19, wherein the test signal is superposed by adding the first signal and the test signal.

23. The method as claimed in claim 19, wherein the first signal is formed by interpolation and modulation of a complex digital baseband input signal.

24. The method as claimed in claim 23, wherein the digital baseband input signal is considered during the comparison of the carrier-frequency test signal component with the tests signal.

25. The method as claimed in claim 23, wherein
before the interpolation and modulation, a baseband clipping method controlled by input parameters is executed on the digital baseband input signal, and
the input parameters are formed by comparing the output signal with the digital baseband input signal.

26. The method as claimed in claim 25, wherein
a clipping threshold is used for the baseband clipping method, and
the clipping threshold is matched adaptively to characteristics of the power amplifier.

27. A method for linearizing the characteristic curve of a power amplifier comprising:
forming a pre-emphasis signal from a second signal by pre-emphasis, the pre-emphasis being controlled using parameters to thereby linearize the characteristic curve of the power amplifier;
performing a carrier-frequency translation, a D/A conversion and a modulation to the pre-emphasis signal to form a carrier frequency input signal;
feeding the carrier frequency input signal to a power amplifier to form a carrier-frequency output signal having a carrier-frequency input signal component;
superposing a test signal onto a digital input first signal to form the second signal so that the output signal has a carrier-frequency test signal component as well as the carrier-frequency input signal component; and
forming the parameters for control of the pre-emphasis by performing a comparison of the carrier-frequency test signal component with the test signal wherein
the test signal is formed in a controlled manner by parameters which are formed from the comparison of the carrier-frequency test signal component with the test signal.

28. The method as claimed in claim 27, wherein for forming the parameters for control of the pre-emphasis, an additional comparison of the carrier-frequency input signal component with the pre-emphasis signal and/or with the digital input first signal is executed.

29. The method as claimed in claim 27, wherein
the power amplifier has a carrier frequency range,
a pulse signal with a time-variant amplitude statistic is used as the test signal, and
the test signal has individual amplitudes which are negligibly disruptive components in carrier frequency ranges adjacent to the carrier frequency range of the power amplifier.

30. The method as claimed in claim 27, wherein the test signal is superposed by adding the digital input first signal and the test signal.

31. The method as claimed in claim 27, wherein the digital input first signal is formed by interpolation and modulation of a complex digital baseband input signal.

32. The method as claimed in claim 31, wherein the digital baseband input signal is considered during the comparison of the carrier-frequency test signal component with the tests signal.

33. The method as claimed in claim 31, wherein
before the interpolation and modulation, a baseband clipping method controlled by input parameters is executed on the digital baseband input signal, and
the input parameters are formed by comparing the output signal with the digital baseband input signal.

34. The method as claimed in claim 33, wherein
a clipping threshold is used for the baseband clipping method, and
the clipping threshold is matched adaptively to characteristics of the power amplifier.

35. A system for linearizing a characteristic curve of a power amplifier, comprising:
a pre-emphasis unit having an input side and output side, which pre-emphasis unit, under the control of parameters, forms from a digital input signal connected on the input side, a pre-emphasis first signal at the output side;
an additive superposition unit connected to the output side of the pre-emphasis unit to superpose a test signal onto the pre-emphasis first signal and form a second signal, the additive superposition unit having an output;
a device having a carrier frequency translation unit, a D/A converter and a modulator, connected to the output of the additive superposition unit to produce a carrier-frequency input signal from the second signal;
a power amplifier that receives the carrier frequency input signal, the power amplifier having an output side, the power amplifier producing an output signal having a carrier frequency test signal component;
a control device connected to the output of the additive superposition device to receive the second signal, and connected to the output side of the power amplifier, the control device performing a comparison of the carrier frequency test signal component with the test signal contained in the second signal to form the parameters for control of the pre-emphasis, and
a pulse generator connected to the control device to form the test signal, the pulse generator being controlled by the parameters for control of the pre-emphasis.

36. The system as claimed in claim 35, wherein
the pre-emphasis unit is additionally connected on its input side to the control device to supply the digital input signal to the control device, and
the digital input signal is used in the formation of the parameters for control of pre-emphasis.

37. The system as claimed in claim 35, wherein the control device forms the parameter for control of the pre-emphasis using a peak detection method, a power estimation method and/or an “NL system identification” method.

38. The system as claimed in claim 35, wherein an interpolation device and modulator are connected upstream from the additive superposition unit such that the pre-emphasis first signal is formed from a complex digital baseband input signal supplied to the interpolation device and modulator.

39. The system as claimed in claim 38, wherein a clipping device for executing a baseband clipping method is connected upstream from the interpolation device and modulator, so that the digital baseband input signal is clipped before reaching the interpolation device and modulator, the clipping device being controlled by the parameters for control of the pre-emphasis.

40. The system as claimed in claim 39, wherein the clipping device is connected to the control device, so that the digital baseband input signal is considered in forming the parameters for control of the pre-emphasis.

41. A system for linearizing the characteristic curve of a power amplifier, comprising:
an additive superposition unit having input and output sides, to form a second signal from a digital input first signal connected on the input side, by superposition of a test signal onto the digital input first signal;
a pre-emphasis unit connected to the output side of the additive superposition unit, the pre-emphasis unit being controlled by parameters to form a pre-emphasis signal from the second signal;
a device having a carrier frequency translation unit, a D/A converter and a modulator whereby a carrier-frequency input signal is formed from the pre-emphasis signal;
a power amplifier that receives the carrier frequency input signal, the power amplifier having an output side, the power amplifier producing an output signal having a carrier frequency test signal component;
a control device connected to the output side of the additive superposition device, whereby the second signal is fed to the control device, the control device being connected to the output side of the power amplifier to perform a comparison of the carrier-frequency test signal component with the test signal contained in the second signal and form the parameters for control of the pre-emphasis, and
a pulse generator connected to the control device to form the test signal, the pulse generator being controlled by the parameters for control of the pre-emphasis.

42. The system as claimed in claim 41, wherein the pre-emphasis unit supplies the pre-emphasis signal to the control device, whereby, the pre-emphasis signal is used to form the parameters for control of the pre-emphasis.

43. The system as claimed in claim 41, wherein the control device forms the parameter for control of the pre-emphasis using a peak detection method, a power estimation method and/or an “NL system identification” method.

44. The system as claimed in claim 41, wherein an interpolation device and modulator are connected upstream from the additive superposition unit such that the digital input first signal is formed from a complex digital baseband input signal supplied to the interpolation device and modulator.

45. The system as claimed in claim 44, wherein a clipping device for executing a baseband clipping method is connected upstream from the interpolation device and modulator, so that the digital baseband input signal is clipped before reaching the interpolation device and modulator, the clipping device being controlled by the parameters for control of the pre-emphasis.

46. The system as claimed in claim 45, wherein the clipping device is connected to the control device, so that the digital baseband input signal is considered in forming the parameters for control of the pre-emphasis.
